(19) United States
(12) Patent Application Publication
(10) Pub. No.: US 2025/0233557 A1
(43) Pub. Date: Jul. 17, 2025

(54) ELECTRONIC FREQUENCY MIXER

(71) Applicant: STMicroelectronics International N.V., Geneva (CH)

(72) Inventor: Valerie DANELON, Grenoble (FR)

(73) Assignee: STMicroelectronics International N.V., Geneva (CH)

(21) Appl. No.: 19/020,078

(22) Filed: Jan. 14, 2025

(30) Foreign Application Priority Data
Jan. 17, 2024 (FR) FR2400436

(51) Int. Cl. H03D 7/14; H03F 3/24

(52) U.S. Cl. CPC H03D 7/1441; H03D 7/1458; H03D 7/1466; H03F 3/245; H03F 2200/294; H03F 2200/451

(57) ABSTRACT

An electronic frequency mixer includes at least one transistor having a front gate, a back gate, a source, and a drain. The source is coupled to a node of application of a radio frequency input signal. The front gate is coupled to a node of application of a first periodic signal at a first frequency. The back gate is coupled to one of: a node of application of the first periodic signal or a node of application of a second periodic signal at the first frequency.

### PRIORITY CLAIM

This application claims the priority benefit of French Application for Patent No. 2400436, filed on Jan. 17, 2024, the content of which is hereby incorporated by reference in its entirety to the maximum extent allowable by law.

### TECHNICAL FIELD

The present description generally concerns electronic frequency mixers and, in particular, frequency mixers comprising transistors.

### BACKGROUND

In electronics, a frequency mixer is a device taking a plurality of input signals and generating one or more output signals having frequencies which are functions of the frequencies of the input signals. For example, an output signal is kept which has a frequency of interest. This frequency of interest may correspond to the sum or difference of the frequencies of the input signals. In particular, a frequency mixer can be designed by using one or a plurality of transistors.

There exists a need to improve the gain and/or the linearity and/or the noise of known frequency mixers.

There is a need in the art to overcome all or part of the disadvantages of known frequency mixers.

### SUMMARY

According to an aspect of the present application, there is provided a second use of an oscillating signal on the back gate of Metal Oxide Semiconductor (MOS) transistors of fully depleted silicon on insulator (FDSOI) type in the case of frequency mixers.

An embodiment provides an electronic frequency mixer comprising: at least one transistor, comprising a front gate, a back gate, a source, and a drain, wherein: the source is coupled to a node of application of a radio frequency input signal; the front gate is coupled to a node of application of a first periodic signal at a first frequency; and the back gate is coupled to one of the node of application of the first periodic signal or a second periodic signal at the first frequency.

According to an embodiment, the at least one transistor is of silicon-on-insulator (SOI) type.

According to an embodiment, either the front gate or the back gate receives the first periodic signal, or the front gate receives the first periodic signal and the back gate receives the second periodic signal, the first and second periodic signals being in phase.

According to an embodiment, the front gate receives the first periodic signal and the back gate receives the second periodic signal, the first and second periodic signals being in phase opposition.

According to an embodiment, the at least one transistor comprises at least four transistors.

According to an embodiment, the four transistors are organized in two pairs, in which: the sources of the first pair of transistors are coupled to a node of application of a first radio frequency input signal; the sources of the second pair of transistors are coupled to a node of application of a second radio frequency input signal, the first and second radio frequency input signals being differential signals; the front and back gates of a first transistor of each pair of transistors are coupled to a node of application of a first periodic signal; and the front and back gates of a second transistor of each pair of transistors are coupled to a node of application of a second periodic signal, the first and second periodic signals being differential signals.

According to an embodiment, the mixer is a passive mixer.

According to an embodiment, the mixer is an active mixer.

According to an embodiment, the input signal is generated by an amplifier stage.

According to an embodiment, the duty cycle of the first periodic signal is identical to the duty cycle of the second periodic signal to within 5%.

According to an embodiment, the drain of the at least one transistor is coupled to the output of the mixer.

Another embodiment provides an electronic circuit comprising: an antenna; and at least one mixer such as described above.

According to an embodiment, the electronic circuit further comprises: a circuit for receiving a radio frequency signal comprising: a) a low-noise amplifier having an input coupled to the antenna; and b) the at least one mixer comprising a first and a second mixer, the radio frequency input signal of each of the first and second mixers being a signal originating from the low-noise amplifier, and the first and/or the second periodic signal of the first mixer being phase-shifted by 90° with respect to the first and/or to the second periodic signal of the second mixer.

According to an embodiment, the electronic circuit further comprises: a circuit for transmitting a radio frequency signal comprising: a) a power amplifier having an output coupled to the antenna; and b) the at least one mixer comprising a third and a fourth mixer, an output of each of the third and fourth mixers being coupled to the power amplifier, the first and/or the second periodic signal of the third mixer being phase-shifted by 90° with respect to the first and/or to the second periodic signal of the fourth mixer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows a cross-section of a fully depleted silicon-on-insulator (FDSOI) n-channel MOS transistor;

FIG. 2 shows a frequency mixer comprising a single transistor;

FIG. 3 shows a graph illustrating the variation of the threshold voltage of the transistor of FIG. 2 according to the voltage applied to the back gate of this transistor;

FIG. 4 shows a passive frequency mixer;

FIG. 5 shows an active frequency mixer;

FIG. 6 shows an electronic circuit comprising at least one frequency mixer;

FIG. 7 shows the noise figure of the frequency mixer of FIG. 4 according to the power of the input signal;

FIG. 8 shows the gain of the frequency mixer of FIG. 4 according to the power of the input signal;

FIG. 9 shows the −1 dB compression points at the input and at the output of the frequency mixer of FIG. 4 according to the back gate voltage applied to the transistors of the circuit;

FIG. 10 shows the −1 dB input compression points and the corresponding first-order output power of the active frequency mixer of FIG. 5 according to the phase difference between the signals applied to the front and back gates of the circuit transistors; and

FIG. 11 shows the gain of the frequency mixer of FIG. 5 according to the power of the input signal and to the signals applied to the front and back gates of the transistors of the mixer.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the method of manufacturing silicon-on-insulator transistors are well known by those skilled in the art, and are not detailed in the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

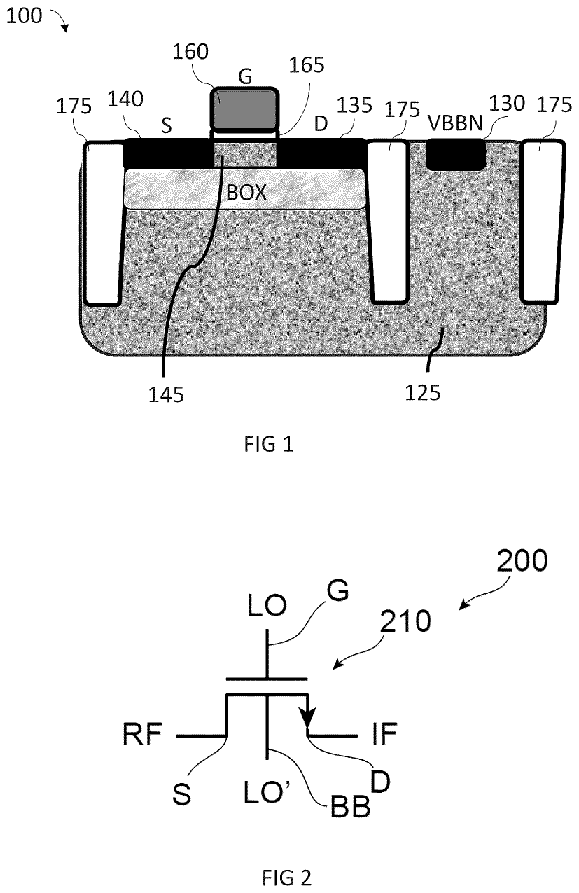

FIG. 1 schematically shows a cross-section of an n-channel MOS transistor 100 of silicon-on-insulator (SOI) type, for example a transistor of fully depleted silicon-on-insulator (FDSOI) type.

N-channel transistor 100 is formed on an n-type doped region 125. Transistor 100 has four connection nodes: a source S, a front gate G, a drain D, and a back gate 130 configured to receive a bias voltage VBBN. The drain D of n-channel transistor 100 corresponds to an n-type doped region 135, and similarly, the source S of n-channel transistor 100 corresponds to an n-type doped region 140. A channel layer 145 separates doped regions 135 and 140. Channel layer 145 is, for example, a thin layer of a semiconductor material.

An insulating oxide layer, referred to as a buried oxide (BOX) layer, for example silicon oxide, is formed between region 125 on the one hand and channel layer 145, and for example the source and the drain, 135 and 140, on the other hand. The thickness of the channel coupling the source and the drain is thus constrained by the BOX layer.

Front gate G is connected to a gate stack comprising a gate conductor 160 and an insulating oxide layer 165.

Transistor 100 is delimited by two shallow trench isolations 175 and back gate 130 is surrounded by an additional shallow trench isolation 175.

Although an n-channel SOI-type transistor is illustrated in FIG. 1, the counterpart exists for a p-channel SOI-type MOS transistor.

As compared with a MOS transistor with no insulating oxide layer, the SOI configuration described hereabove enables to bias the doped region 125 of a transistor 100 with a significant voltage range, for example a range wider than that used for the substrate of a transistor with no insulating oxide layer. The contact with back gate 130 is considered a second gate which will influence the conduction of channel 145, with a gain lower than the gain of front gate G.

FIG. 2 shows a frequency mixer 200 comprising a single transistor 210.

Mixer 200 comprises, for example, an n-channel transistor of silicon-on-insulator (SOI) type 210, which is, for example, formed in the same way as the transistor 100 of FIG. 1. The mixer takes as an input a radio frequency signal RF applied to its source(S), a first periodic signal LO applied to its front gate (G) and a second periodic signal LO′ applied to its back gate (BB), corresponding to the substrate contact 130 of the transistor 100 of FIG. 1. The first and second periodic signals LO, LO′ may in certain cases be the same signal duplicated on the two gates. In other embodiments, the first and second periodic signals are two distinct signals and, for example, have the same frequency to within 5% and, for example, originate from a same signal generator. The first and second periodic signals may also originate from two separate signal generators. A phase shift between the first and second periodic signals is possible.

The RF signal corresponds, for example, to an input signal of the mixer, configured to be modulated by mixer 200, and signal LO corresponds, for example, to a periodic signal configured to modulate the RF signal.

The signal supplied at an output by the mixer is the IF signal present at the drain (D) of transistor 210. The frequency of the IF signal corresponds to a difference between the input frequencies applied to the RF source and to the front gate LO of the transistor.

The conversion of the input frequencies into an output frequency can be characterized by a plurality of parameters of mixer 200, including the gain, the noise, and the linearity.

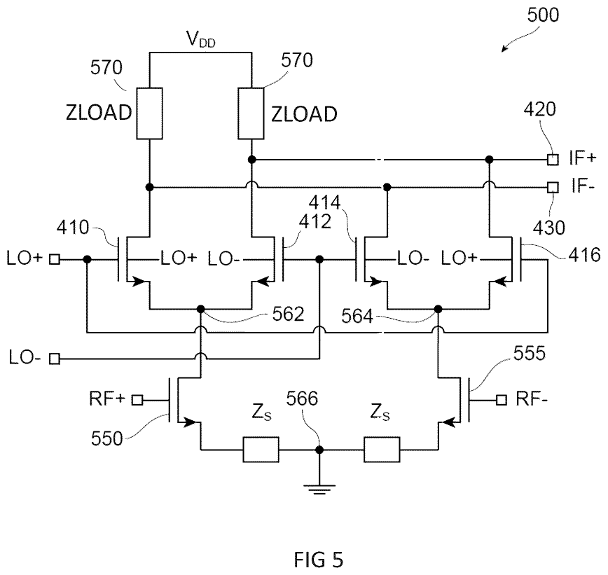

The gain corresponds to the ratio of the amplitudes of the RF and IF signals (in power, voltage, or current) and quantifies the power loss or amplification that a signal undergoes when passing through a mixer. The noise factor NF quantifies the addition of noise to the signal due to a mixer. These two parameters are directly dependent on the threshold voltage of the transistors present in the mixer, as detailed hereafter for the circuit of FIG. 4.

A mixer similar to that of FIG. 2 could be formed with a p-channel transistor instead of the n-channel transistor.

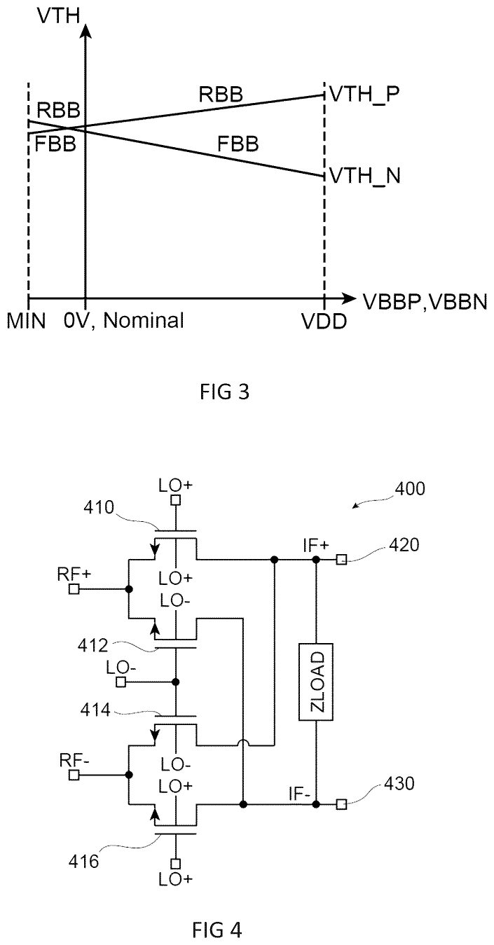

FIG. 3 shows a graph illustrating the variation of the threshold voltage of an n-channel SOI transistor, such as the transistor 100 of FIG. 1, and of a corresponding p-channel SOI transistor, according to the voltage applied to the back gate of these transistors. The graph of FIG. 3 in particular shows the threshold voltage (VTH) of the p-channel (VTH_P) and n-channel (VTH_N) SOI transistor according to the voltage applied to the back gate of the transistor (VBBP, VBBN).

The BOX insulating layer present in a SOI transistor enables to apply a relatively significant back gate voltage VBBN, VBBP and to modify the threshold voltage of the transistor.

For the n-channel transistor, threshold voltage VTH_N is continuously decreased for a positive back gate voltage (FBB, forward body biasing) and continuously increased for a negative back gate voltage (RBB, reverse body biasing).

In the non-conductive mode, that is, when the voltage between the front gate and the source is lower than the threshold voltage, increasing the threshold voltage enables to decrease the residual current flowing between the source and the drain.

Conversely, in the conductive mode, that is, when the voltage between the front gate and the source is higher than the threshold voltage, decreasing the threshold voltage enables to have a higher electric current flow between the source and the drain of the transistor. Thus, using the back gate voltage of SOI transistors in a mixer allows a rise in the gain of the mixer.

For the p-channel transistor, threshold voltage VTH_P also varies with the voltage applied to back gate VBBP, but positively. The threshold voltage increases with a positive voltage on the back gate (RBB) and decreases with a negative voltage on the back gate (FBB).

FIG. 4 shows a passive frequency mixer 400 according to an embodiment of the present disclosure.

In the embodiment illustrated in FIG. 4, the input and output signals are differential-mode signals, the RF input signal being formed of differential signals RF+ and RF−, periodic signal LO being formed of differential signals LO+ and LO−, and the IF output signal being formed of differential signals IF+ and IF−.

The operating principle of this mixer 400 is similar to the mixer 200 described in relation with FIG. 2, but the latter comprises four transistors 410, 412, 414, 416 to take into account the differential signals. In this embodiment, the four transistors are n-channel MOS transistors of SOI type. In another embodiment, a similar mixer could be formed with p-channel MOS transistors of SOI type.

Input signal RF+ is applied to a node coupled, preferably connected, to the sources S of transistors 410 and 412.

Input signal RF− is applied to a node coupled, preferably connected, to the sources S of transistors 414 and 416.

Periodic signal LO+ is coupled, preferably connected, to the front and back gates of transistors 410 and 416.

Periodic signal LO− is coupled, preferably connected, to the front and back gates of transistors 412 and 414.

The drains of transistors 410 and 414 are coupled, preferably connected, to a first output terminal 420 of the mixer supplying output signal IF+.

The drains of transistors 412 and 416 are coupled, preferably connected, to a second output terminal 430 of the mixer supplying output signal IF−.

Electronic components configured to process output signals IF+, IF− may be connected between the output terminals 420 and 430 of mixer 400 and are represented by an impedance ZLOAD.

For the mixer 400 of FIG. 4, at the first order, gain G is dependent on the equivalent resistance of a transistor in the on mode (R_{ON}) and the equivalent impedance of a transistor in the off mode (ZOFF) specific to the transistor.

The noise figure NF is dependent on R_{ON} and on the gain.

The equivalent resistance of a transistor in the on mode, R_{ON}, is inversely proportional to the difference between VGS and VTH.

Thus, by using SOI-type transistors 210, 215 in a frequency mixer 400, the voltage applied to back gates VBBN, VBBP varies the threshold voltage VTH of the transistors and influences the quality parameters of the frequency mixer.

FIG. 5 shows an active frequency mixer 500.

Certain elements of FIG. 5 are similar to those of FIG. 4 and have been referenced with the same reference numerals and will not be described again in detail.

Frequency mixer 500 comprises four SOI-type MOS transistors 410, 412, 414, 416 similarly connected to frequency mixer 400.

Transistors 410 and 416 receive on their front gate a first periodic signal LO+ and transistors 410 and 416 receive on their back gate a second periodic signal LO+, which may be phase-shifted or not with respect to the first periodic signal LO+.

Transistors 412 and 414 receive on their front gate a first periodic signal LO−, and transistors 412 and 414 receive a second periodic signal LO− on their back gate, which may be phase-shifted or not with respect to the first periodic signal LO−.

Radio-frequency differential signal RF+ and RF− is, in frequency mixer 500, amplified, for example by an amplifier circuit. In the example of FIG. 5, the amplification circuit comprises two MOS transistors 550 and 555 and load or matching or degeneration elements.

For example, the drain of transistor 550 is coupled to a node 562, which is connected to the sources of transistors 410 and 412. Signal RF+ is applied to the front gate of transistor 550 and its source is, for example, coupled to a node 566 via a first one of the two impedances Z_{S}. Similarly, the drain of transistor 555 is coupled to a node 564 which is connected to the sources of transistors 414 and 416. Signal RF− is applied to the front gate of transistor 555 and its source is, for example, coupled to node 566 via a second one of the two impedances Z_{S}. Node 566 may, for example, also be coupled to a ground rail or to the drain of a transistor. The source of said transistor is, for example, coupled to the ground of circuit 500 and its front gate is, for example, biased by a fixed voltage to modulate the gain applied to signals RF+ and RF−.

In the same way as for mixer 400, the drains of transistors 410 and 414 are coupled, preferably connected, to the output terminal 430 supplying output signal IF−, and the drains of transistors 412 and 416 are coupled, preferably connected, to the output terminal 420 supplying output signal IF+.

Electronic components configured to process output signals IF+, IF− may be connected between the output terminals 420 and 430 of mixer 500 and are represented by two impedances ZLOAD 570, coupled between the output terminals 420, 430 and a power supply voltage rail V_{DD}.

Although in the examples shown in FIGS. 4 and 5, a same signal LO+ is applied to the front and back gates of transistors 410, 416, in other embodiments, it would be possible to apply two distinct signals to the front and back gates, these signals having, for example, the same frequency to within 5%. Similarly, although in the examples of FIGS. 4 and 5, a same signal LO− is applied to the front and back gates of transistors 412, 414, in other embodiments, it would be possible to apply two distinct signals to the front and back gates, these signals having, for example, the same frequency to within 5%.

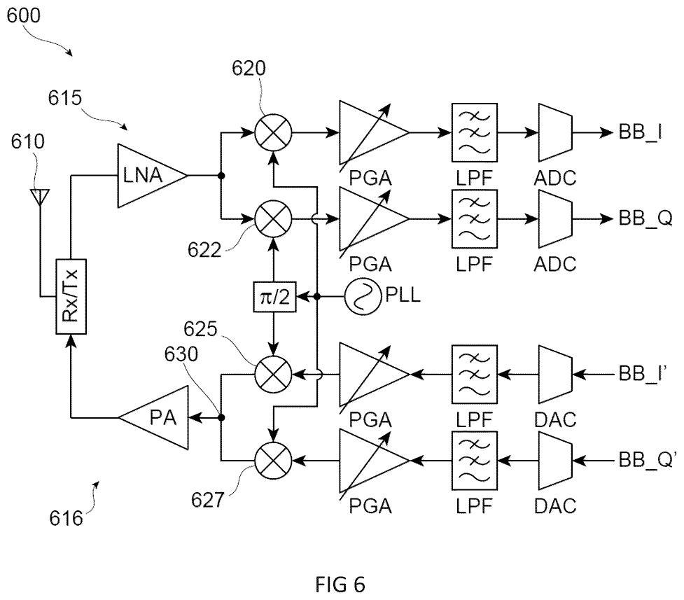

An example of a transceiver is described hereafter in relation with FIG. 6 as a possible example of application of the active or passive mixer of the present disclosure. Of course, other possible applications of this mixer are known by those skilled in the art.

FIG. 6 shows an electronic circuit 600 comprising at least one frequency mixer according to FIG. 2, FIG. 4 or FIG. 5.

Circuit 600 is a transceiver enabling to receive or to transmit a piece of information. For example, circuit 600 enables to receive or to transmit an encoded binary piece of information, for example in phase-shift keying.

The piece of information is received by an input Rx or transmitted from an Tx output of the circuit by an antenna 610. Input/output Rx/Tx is, for example, coupled to a receive chain 615 and to a transmit chain 616.

Receive chain 615 comprises a low-noise amplifier LNA configured to receive an RF signal from antenna 610, and to amplify this signal. The output of the low-noise amplifier LNA is coupled to the input of a first mixer 620 of a first sub-chain for processing a first (in phase) component I of the RF input signal, and to the input of a second mixer 622 of a second sub-chain for processing a second (quadrature phase) component Q of the RF input signal. Mixers 620 and 622 are, for example, implemented by the above-described mixers 300, 400, or 500.

Circuit 600 comprises, for example, a phase-locked loop (PLL) configured to generate periodic signal LO. In the differential case, the periodic signal generated by the PLL is formed of a component LO+ and of a component LO−. The PLL output is coupled to the front and back gates of mixer 620.

Mixer 620 is configured to modulate the RF input signal with the periodic signal LO originating from the PLL. The output of mixer 620 is coupled to the input of a first programmable gain amplifier PGA configured to amplify the IF output signal of mixer 620. The output of the first PGA is coupled to the input of a first low-pass filter LPF configured to filter the output signal of the PGA. The output of the first LPF is coupled to the input of a first analog-to-digital converter ADC configured to convert the analog signal at the output of the first LPF into a first digital signal BB_I.

The output of the PLL is also coupled to the input of a π/2 module configured to shift the phase of the periodic signal generated by the PLL by 90°. In the differential case, the two components are phase-shifted by 90°. The output of the π/2 module is coupled to the front and back gates of the mixer 622 of the sub-chain for processing the Q component of the RF signal.

Mixer 622 is configured to modulate the RF input signal with the periodic signal LO phase-shifted by 90° originating from the π/2 module. The output of mixer 622 is coupled to the input of a second programmable-gain amplifier PGA configured to amplify the IF output signal from mixer 622. The output of the second PGA is coupled to the input of a second low-pass filter LPF configured to filter the output signal of the second PGA. The output of the second LPF is coupled to the input of a second analog-to-digital converter ADC configured to convert the analog signal at the output of the second LPF into a second digital signal BB_Q.

The analog RF signal received by antenna 610 is thus separated by processing chain 615 into two digital signals BB_I and BB_Q, corresponding to the I and Q components of the demodulated signal, the components being phase-shifted by 90° with respect to each other.

Conversely, the transmission of an RF signal by antenna 610 comprises, for example, the processing of two digital components (in phase) BB_I′ and (quadrature phase) BB_Q′ by the second processing chain 616.

Signal BB_I′ is processed by a first processing sub-chain and signal BB_Q′ is processed by a second processing sub-chain.

Signal BB_I′ is received by a first digital-to-analog converter DAC configured to convert signal BB_I′ into an analog signal and having its output coupled to the input of a third LPF configured to filter the output signal of the first DAC. The output of the third LPF is coupled to the input of a third PGA configured to amplify the output signal of the third LPF. The output of the third PGA is coupled to the input of mixer 625. The output of the π/2 module is also coupled to the front and back gates of mixer 625, which is configured to modulate the signal corresponding to the I component by the periodic signal LO phase-shifted by 90° by the π/2 module. The output of mixer 625 is coupled to the input of a power amplifier PA.

Signal BB_Q′ is received by a second digital-to-analog converter DAC configured to convert signal BB_Q′ into an analog signal and having its output coupled to the input of a fourth LPF configured to filter the output signal of the second DAC. The output of the fourth LPF is coupled to the input of a fourth PGA configured to amplify the output signal of the fourth LPF. The output of the fourth PGA is coupled to the input of mixer 627. The output of the LPF is also coupled to the front and back gates of mixer 627, which is configured to modulate the signal corresponding to the Q component by the periodic signal LO generated by the PLL. The output of mixer 627 is coupled to the input of power amplifier PA.

The output signals of mixers 625 and 627 are superimposed at the input of the power amplifier, which is configured to amplify the combined analog signal. The output of the PA is coupled to the output Tx of circuit 600, configured to transmit the signal via antenna 610.

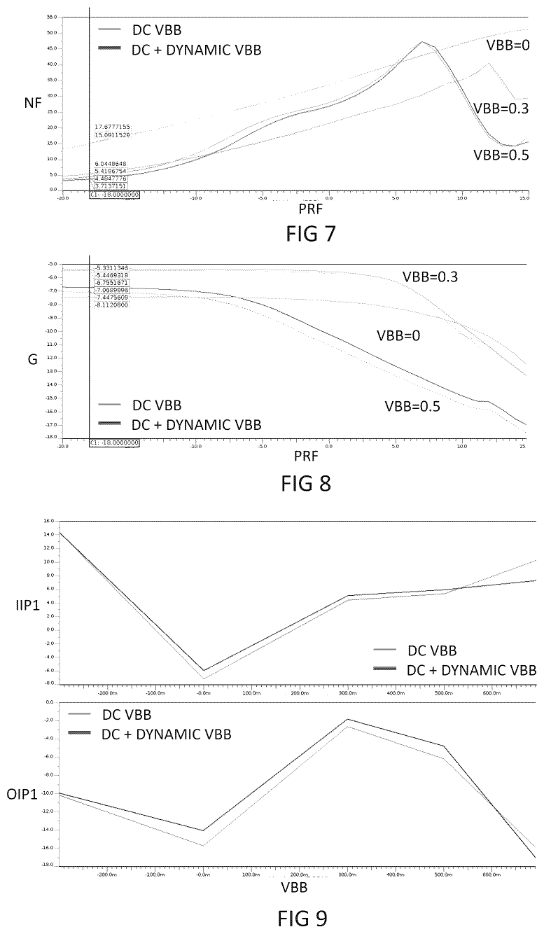

FIGS. 7 to 9 show quantities characteristic of the circuit described in relation with FIG. 4, resulting from simulations carried out with a DC back gate voltage VBB “DC VBB” or a back gate voltage VBB comprising a DC component and a periodic component “DC+dynamic VBB”.

FIG. 7 shows the noise figure NF of the frequency mixer of FIG. 4 according to the power of the input signal PRF in dBm for a DC back gate voltage VBB (“DC VBB”) or a periodic back gate voltage with a DC offset (“DC+dynamic VBB”) for three DC values 0 V (“VBB=0”), 0.3 V (“VBB=0.3”), and 0.5 V (“VBB=0.5”). The noise figure is the degradation of the signal-to-noise ratio between the input and the output of a device.

For an input power ranging from −20 dB to 7 dB, the noise figure is decreased by the use of a back gate voltage oscillating at a frequency close to or equal to the frequency of the input RF signal.

FIG. 8 shows the gain G of the passive frequency mixer 400 of FIG. 4 according to the power of the input signal PRF for a DC back gate voltage VBB “DC VBB” or a periodic back gate voltage with a DC offset “DC+dynamic VBB” for three DC values 0V (“VBB=0”), 0.3 V (“VBB=0.3”), and 0.5 V (“VBB=0.5”). The gain of the circuit represents the ratio of the amplitudes of the input and output signals of the circuit.

For an input power ranging from −20 dB to 15 dB, the gain is higher for a periodic back gate voltage.

FIG. 9 shows the −1 dB compression points at the input IIP1 and at the output OIP1 of the passive frequency mixer 400 of FIG. 4 according to the DC back gate voltage applied to the transistors of the circuit for a DC back gate voltage VBB “DC VBB” or a periodic back gate voltage with a DC offset, “DC+dynamic VBB”. The −1 dB compression point corresponds to the input or output power level resulting from a 1-dB attenuation of the output power with respect to the straight line obtained at low power of the output power according to the input power in dBm.

For a back gate voltage ranging from −200 mV to 500 mV, compression points IIP1 and OIP1 are higher for a periodic back gate voltage. These parameters are representative of the compression of a signal caused by a circuit.

In conclusion, the use of SOI transistors coupled with the application of a periodic signal to the back gate of the transistors allows a decrease of the noise generated by the frequency mixer and/or an increase of the gain and/or of the linearity.

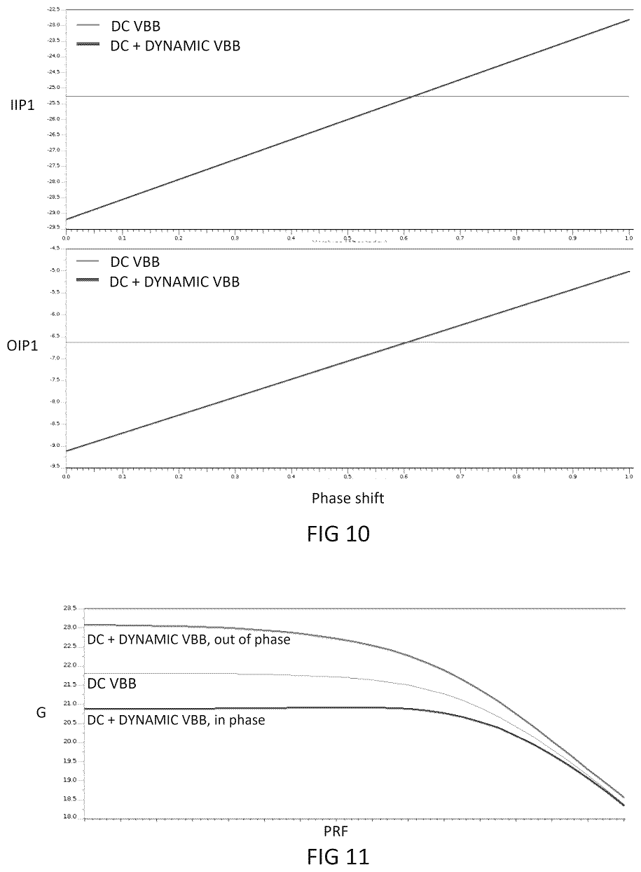

FIGS. 10 and 11 illustrate the impact of the phase difference between the periodic signals applied to the front and back gates of the SOI transistors in the active frequency mixer 500 of FIG. 5. The behavior is, in these examples, different for the example of passive mixer 400 and the example of active mixer 500.

FIG. 10 shows the −1 dB compression points at input IIP1 and the corresponding first-order output power OIP1 of the active frequency mixer of FIG. 5 according to the phase difference between the signals applied to the front and back gates (“Phase shift”) of the circuit transistors for a DC back gate voltage VBB (“DC VBB”) or a periodic back gate voltage with a DC offset “DC+dynamic VBB”. In the case of the active circuit of FIG. 5, two periodic signals in phase (Phase shift=1) generate compression points IIP1 and OIP1 higher than the values obtained with DC signals. Conversely, two periodic signals in phase opposition (Phase shift=0) generate compression points IIP1 and OIP1 lower than the values obtained with DC signals. In other embodiments, with a different definition of signals LO, there could also be an improvement of the linearity with two periodic signals in phase opposition.

FIG. 11 shows the gain G of the frequency mixer of FIG. 5 according to the power of the input signal PRF for a DC back gate voltage VBB “DC VBB”, for periodic front and back gate voltages with a DC offset and in phase “DC+dynamic VBB, in phase”, and for periodic front and back gate voltages with a DC offset and in phase opposition “DC+dynamic VBB, out of phase”. In the example of the mixer of FIG. 5, the gain of the circuit is at its maximum for periodic signals in phase opposition, and in particular higher than DC signals, and it is minimum for periodic signals in phase.

Various embodiments and variants have been described. Those skilled in the art will understand that certain features of these various embodiments and variants may be combined, and other variants will occur to those skilled in the art. In particular, the circuits formed with n-channel transistors could be adjusted for p-channel transistors.

1. An electronic frequency mixer, comprising:
at least one transistor having a front gate, a back gate, a source, and a drain;
wherein:
the source is coupled to a node of application of a radio frequency input signal;
the front gate is coupled to a node of application of a first periodic signal at a first frequency; and
the back gate is coupled to one of: a node of application of the first periodic signal or a node of application of a second periodic signal at the first frequency.

2. The electronic frequency mixer according to claim 1, wherein the at least one transistor is of silicon-on-insulator type.

3. The electronic frequency mixer according to claim 1, wherein the front and back gates receive the first periodic signal.

4. The electronic frequency mixer according to claim 1, wherein the front gate receives the first periodic signal and the back gate receives the second periodic signal, the first and second periodic signals being in phase.

5. The electronic frequency mixer according to claim 1, wherein the front gate receives the first periodic signal and the back gate receives the second periodic signal, the first and second periodic signals being in phase opposition.

6. The electronic frequency mixer according to claim 1, wherein the at least one transistor comprises a first pair of transistors and a second pair of transistors, and wherein:
sources of transistors in the first pair of transistors are coupled to a node of application of a first radio frequency input signal;
sources of transistors in the second pair of transistors are coupled to a node of application of a second radio frequency input signal, the first and second radio frequency input signals being differential signals;
front and back gates of a first transistor of each of the first and second pairs of transistors are coupled to a node of application of a first periodic signal; and
front and back gates of a second transistor of each of the first and second pairs of transistors are coupled to a node of application of a second periodic signal, the first and second periodic signals being differential signals.

7. The electronic frequency mixer according to claim 6, wherein the mixer is a passive mixer.

8. The electronic frequency mixer according to claim 6, wherein the mixer is an active mixer.

9. The electronic frequency mixer according to claim 8, wherein the radio frequency input signal is generated by an amplifier stage.

10. The electronic frequency mixer according to claim 6, wherein a duty cycle of the first periodic signal is identical to a duty cycle of the second periodic signal to within 5%.

11. The electronic frequency mixer according to claim 6, wherein the front and back gates of the first transistor of each of the first and second pairs of transistors receive the first periodic signal in phase opposition, and wherein the front and back gates of the second transistor of each of the first and second pairs of transistors receive the second periodic signal in phase opposition.

12. The electronic frequency mixer according to claim 1, wherein the drain of the at least one transistor is coupled to the output of the mixer.

13. An electronic circuit, comprising:
an antenna; and
at least one electronic frequency mixer according to claim 1.

14. The electronic circuit according to claim 13, further comprising a circuit for receiving a radio frequency signal comprising:
a) a low-noise amplifier having an input coupled to the antenna; and
b) the at least one mixer comprising a first mixer and a second mixer, the radio frequency input signal of each of the first and second mixers being a signal originating from the low-noise amplifier, and the first and/or the second periodic signal of the first mixer being phase-shifted by 90° (π/2) with respect to the first and/or to the second periodic signal of the second mixer.

15. The electronic circuit according to claim 13, further comprising a circuit for transmitting a radio frequency signal comprising:
a) a power amplifier having an output coupled to the antenna; and
b) the at least one mixer comprising a third mixer and a fourth mixer, an output of each of the third and fourth mixers being coupled to the power amplifier, the first and/or the second periodic signal of the third mixer being phase-shifted by 90° (π/2) with respect to the first and/or to the second periodic signal of the fourth mixer.
